(19) United States
(12) Patent Application Publication
(10) Pub. No.: US 2024/0349620 A1
(43) Pub. Date: Oct. 17, 2024

(54) MTJ PILLAR HAVING TEMPERATURE-INDEPENDENT DELTA

(71) Applicant: International Business Machines Corporation, Armonk, NY (US)

(72) Inventors: Daniel Worledge, San Jose, CA (US); Guohan Hu, Yorktown Heights, NY (US)

(21) Appl. No.: 18/752,170

(22) Filed: Jun. 24, 2024

Related U.S. Application Data
(63) Continuation of application No. 16/271,317, filed on Feb. 8, 2019.

(51) Int. Cl. H10N 50/80; G11C 11/16; H01F 10/32; H01F 41/34; H10B 61/00; H10N 50/01; H10N 50/85

(52) U.S. Cl. CPC H10N 50/80; G11C 11/161; H01F 10/3259; H01F 10/3286; H01F 10/329; H10B 61/00; H10N 50/85; H01F 41/34; H10N 50/01

(57) ABSTRACT

A magnetoresistive random access memory (MRAM) including spin-transfer torque (STT) MRAM is provided that has enhanced data retention. The enhanced data retention is provided by constructing a MTJ pillar having a temperature-independent Delta, where Delta is Delta=Eb/kt, wherein Eb is the activation energy, k is the Boltzmann's constant, and T is the absolute temperature. Notably, the present application provides a way for EB to actually increase with temperature, which can cancel the effect of the term KT, resulting in a temperature independent Delta.

### BACKGROUND

The present application relates to a magnetic tunnel junction (MTJ) containing device. More particularly, the present application relates to a magnetoresistive random access memory (MRAM), such as spin-transfer torque (STT) MRAM, which has enhanced data retention.

MRAM is a viable memory option for stand alone and embedded applications such as, for example, internet of things (IoT), automobile, or artificial intelligence (AI). MRAM is a non-volatile random access memory technology in which data is stored by magnetic storage elements. These elements are typically formed from two ferromagnetic plates, each of which can hold a magnetization, separated by a thin dielectric layer, i.e., the tunnel barrier layer. One of the two plates is a permanent magnetic set to a particular polarity; the other plate's magnetization can be changed to match that of an external field to store memory.

One type of MRAM is spin-transfer torque (STT) MRAM. STT MRAM has the advantages of lower power consumption and better scalability over conventional MRAM which uses magnetic fields to flip the active elements. In STT MRAM, spin-transfer torque is used to flip (switch) the orientation of the magnetic free layer. Moreover, spin-transfer torque technology has the potential to make possible MRAM devices combining low current requirements and reduced cost; however, the amount of current needed to reorient (i.e., switch) the magnetization is at present too high for most commercial applications.

STT MRAM uses a two-terminal device with a magnetic tunnel junction (MTJ) pillar composed of a magnetic reference layer, a tunnel barrier layer, and a magnetic free layer. The magnetization of the magnetic reference layer is fixed in one direction and a current passed up through the MTJ pillar makes the magnetic free layer anti-parallel to the magnetic reference layer, while a current passed down through the MTJ pillar makes the magnetic free layer anti-parallel to the magnetic reference layer. A smaller current (of either polarity) is used to read the resistance of the device, which depends on the relative orientations of the magnetic reference layer and the magnetic free layer.

One key issue with conventional MRAM including STT MRAM is that data retention gets worse at high temperatures. Data retention depends on the parameter Delta=Eb/kT, wherein Eb is the activation energy, k is the Boltzmann's constant, and T is the absolute temperature. Even if Eb is independent of temperature, Delta still deceases as T increases. There is thus a need to provide a MRAM including STT MRAM in which data retention improves as the temperature increases.

### SUMMARY

A magnetoresistive random access memory (MRAM) including STT MRAM is provided that has enhanced data retention. The enhanced data retention is provided by constructing a MTJ pillar having a temperature-independent Delta, where Delta is as defined above. Notably, the present application provides a way for Eb to actually increase with temperature, which can cancel the effect of the term kT, resulting in a temperature independent Delta.

In one embodiment, the MTJ pillar of the MRAM includes a tunnel barrier layer located between a magnetic reference layer and a magnetic free layer, wherein the magnetic free layer is composed of a material whose magnetization increases with increasing temperature.

In another embodiment, the magnetic tunnel junction (MTJ) pillar of the MRAM includes a tunnel barrier layer located between a magnetic reference layer and a multilayered magnetic free layer structure that includes a first magnetic free layer and a second magnetic free layer separated by a non-magnetic layer. In this embodiment, the second magnetic free layer is composed of a material whose magnetization increases with increasing temperature.

### BRIEF DESCRIPTION OF THE DRAWINGS

FIG. 1 is a cross sectional view of an exemplary MTJ pillar of the present application and including a tunnel barrier layer located between a magnetic reference layer and a magnetic free layer, wherein the magnetic free layer is composed of a material whose magnetization increases with increasing temperature.

FIG. 2 is a cross sectional view of another exemplary MTJ pillar of the present application and including a tunnel barrier layer located between a magnetic reference layer and a multilayered magnetic free layer structure that includes a first magnetic free layer and a second magnetic free layer separated by a non-magnetic layer, wherein the second magnetic free layer is composed of a material whose magnetization increases with increasing temperature.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

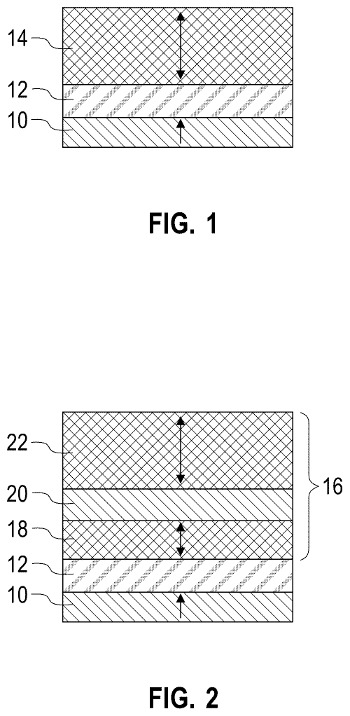

The present application provides magnetic tunnel junction (MTJ) pillars, such as shown, for example, in FIGS. 1 and 2, that can provide improved data retention to a MRAM including STT MRAM. Notably, each of the MTJ pillars is designed to include a magnetic free layer that is composed of a material whose magnetization increases with increasing temperature so that the moment of the magnetic free layer (or a part of the magnetic free layer) increases as the temperature increases. This is unusual (for ferromagnetics which are typically used as the magnetic free layer), the magnetization always decreases with increasing temperature.

The Neel-Brown theory of magnetic switching says that the probability of the magnetic free layer switching by thermal activation depends on the parameter Eb/kT according to the exponential distribution P (t)=1−exp (−t/(t0 exp (Eb/kT))). Here Eb is the energy barrier or thermal activation energy, k is Boltzmann's constant, T is absolute temperature, and t0 is a characteristic time ˜1 ns. As T increases, for most materials Eb decreases. In addition, 1/kT decreases. Therefore Eb/kT decreases from two factors. In the present application, as T increases, Eb increases because the moment increases. Still 1/kT will decrease. But the ratio of Eb/kT could stay constant, since while 1/kT goes down, Eb goes up.

In the present application, the magnetic free layer is composed of a ferrimagnetic material that has populations of atoms with opposing magnetic moments, as in antiferromagnetism; however, the opposing moments are unequal and a spontaneous magnetization remains. In the present application, the ferrimagnetic material can be a rare earth metal containing transition metal composition, RE-TM, wherein RE is a rare earth metal, and TM is a transition metal selected from the group consisting of cobalt (Co), iron (Fe), nickel (Ni), and alloys thereof.

The term “rare earth metal” is used throughout the present application to denote a metallic element comprising the lanthanides, scandium (Sc) and yttrium (Y). The term “lanthanide” is used throughout the present application to denote one of the fifteen metallic elements with atomic numbers 57 through 71. The lanthanides include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu).

In rare earth metal containing transition metal compositions, the rare earth metal moment aligns anti-parallel to the moment of the transition metal(s), and has stronger temperature dependence. If at room temperature the rare earth metal moment is larger than the moment of the transition metal(s), then as temperature increases and both moments decreases (but the moment of the rare earth decreases more than the moment of the transition metal(s)) the net moment will increase.

By utilizing a ferrimagnetic material as the magnetic free layer, as the moment increases, the Eb of the magnetic free layer also increases. If this is tuned to compensate for the change in kT, then Delta will be independent of temperature and the MRAM including a STT MRAM will have good data retention over a temperature range of from −40° C. to 125° C.

Referring first to FIG. 1, there is illustrated an exemplary MTJ pillar of the present application. The MTJ pillar of FIG. 1 includes a tunnel barrier layer 12 located between a magnetic reference layer 10 and a magnetic free layer 14. In accordance with the present application, the magnetic free layer 14 is composed of a material whose magnetization increases with increasing temperature. In FIG. 1, the arrow within the magnetic reference layer 10 shows a possible orientation of that layer and the double headed arrows in the magnetic free layer 14 illustrates that the orientation in that layer can be switched.

Although not shown, the MTJ pillar of FIG. 1 is located between a bottom electrode and a top electrode. The bottom and top electrodes are composed of an electrically conductive material such as, for example, Ta, TaN, Ti, TiN, Ru, RuN, RuTa, RuTaN, Co, CoWP, CON, W, WN or any combination thereof. The bottom electrode is typically located on a surface of an electrically conductive structure that is embedded in an interconnect dielectric material layer. Another electrically conductive structure, which is typically embedded in another interconnect dielectric material layer, contacts a surface of the top electrode. An encapsulation material may be located laterally adjacent to the MTJ pillar. The MTJ pillar is typically cylindrical in shape, however the MTJ pillar may have other asymmetrical shapes.

The orientation of the MTJ pillar may be as shown in FIG. 1, with the magnetic free layer 14 being located above the magnetic reference layer 10, or the orientation can be rotated 180° such that the magnetic reference layer 10 is located above the magnetic free layer 14.

The MTJ pillar shown in FIG. 1 can be formed by first providing a MTJ stack that includes blanket layers of the various MTJ pillar materials. The blanket layers of the MTJ pillar materials can be formed by utilizing one or more deposition processes such as, for example, plating, sputtering, plasma enhanced atomic layer deposition (PEALD), plasma enhanced chemical vapor deposition (PECVD) or physical vapor deposition (PVD). After forming the MTJ stack, the MTJ stack is patterned into the MTJ pillar. In some embodiments, the MTJ stack is patterned by etching utilizing a top electrode as an etch mask. In other embodiments, the MTJ stack can be patterned by photolithography and etching.

The magnetic reference layer 10 has a fixed magnetization. The magnetic reference layer 10 may be composed of a metal or metal alloy (or a stack thereof) that includes one or more metals exhibiting high spin polarization. In alternative embodiments, exemplary metals for the formation of the magnetic reference layer 10 include iron, nickel, cobalt, chromium, boron, or manganese. Exemplary metal alloys may include the metals exemplified by the above. In another embodiment, the magnetic reference layer 10 may be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. The thickness of magnetic reference layer 10 will depend on the material selected. In one example, magnetic reference layer 10 may have a thickness from 0.3 nm to 3 nm.

The tunnel barrier layer 12 is composed of an insulator material and is formed at such a thickness as to provide an appropriate tunneling resistance. Exemplary materials for the tunnel barrier layer 12 include magnesium oxide, aluminum oxide, and titanium oxide, or materials of higher electrical tunnel conductance, such as semiconductors or low-bandgap insulators. The thickness of the tunnel barrier layer 12 will depend on the material selected. In one example, the tunnel barrier layer 12 may have a thickness from 0.5 nm to 1.5 nm.

The magnetic free layer 14 is composed of a material whose magnetization increases with increasing temperature. Notably, the magnetic free layer 14 is composed of a ferrimagnetic material, as defined above. In one embodiment, the ferrimagnetic material is a rare earth metal containing transition metal composition, RE-TM, wherein RE is a rare earth metal, as defined above, and TM is a transition metal selected from the group consisting of cobalt (Co), iron (Fe), nickel (Ni), and alloys thereof. That is, RE is one of, scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu).

In one embodiment, the transition metal, TM, of the rare earth metal containing transition metal composition, RE-TM, is an alloy of Co and Fe, and the rare earth metal is one of terbium (Tb) and gadolinium (Gd). In one example, the rare earth metal containing transition metal composition is Tb₁₋ₓ(Fe_{1-y}CO_{y})ₓ, wherein x is from 0.74 to 0.78 and y is from 0.16 to 0.18. In another example, the rare earth metal containing transition metal composition is Tb₁₋ₓ(Fe_{1-y}Co_{y})ₓ, wherein x is 0.76 and y is 0.17.

The magnetic free layer 14 has a perpendicular magnetic anisotropy field which can be from 1 kOe to 10 kOe. The magnetic free layer 14 has a thickness which can be from 1.5 nm to 4 nm; although other thicknesses can also be used in the present application as the thickness of the magnetic free layer 16.

In some embodiments (not shown), a MTJ cap layer can be formed as a topmost component of the MTJ pillar of FIG. 1. When present, the MTJ cap layer may be composed of Nb, NbN, W, WN, Ta, TaN, Ti, TiN, Ru, Mo, Cr, V, Pd, Pt, Rh, Sc, Al or other high melting point metals or conductive metal nitrides. The MTJ cap layer may be formed utilizing a deposition process including, for example, CVD, PECVD, ALD, PVD, sputtering, chemical solution deposition or plating. The MTJ cap layer may have a thickness from 2 nm to 25 nm; other thicknesses are possible and can be used in the present application as the thickness of the MTJ cap layer.

Referring now to FIG. 2, there is illustrated another exemplary MTJ pillar of the present application and including a tunnel barrier layer 12 located between a magnetic reference layer 10 and a multilayered magnetic free layer structure 16. The multilayered magnetic free layer structure 16 includes a first magnetic free layer 18 and a second magnetic free layer 22 separated by a non-magnetic layer 20. In this embodiment, the second magnetic free layer 22 is composed of a material whose magnetization increases with increasing temperature. In FIG. 2, the arrow within the magnetic reference layer 10 shows a possible orientation of that layer and the double headed arrows in the first and second magnetic free layers (18 and 22) illustrate that the orientation in those layers can be switched.

Although not shown, the MTJ pillar of FIG. 2 is located between a bottom electrode and a top electrode. The bottom and top electrodes are composed of an electrically conductive material such as, for example, Ta, TaN, Ti, TiN, Ru, RuN, RuTa, RuTaN, Co, CoWP, CON, W, WN or any combination thereof. The bottom electrode is typically located on a surface of an electrically conductive structure that is embedded in an interconnect dielectric material layer. Another electrically conductive structure, which is typically embedded in another interconnect dielectric material layer, contacts a surface of the top electrode. An encapsulation material may be located laterally adjacent to the MTJ pillar. The MTJ pillar is typically cylindrical in shape, however the MTJ pillar may have other asymmetrical shapes.

The orientation of the MTJ pillar may be as shown in FIG. 2, with the multilayered magnetic free layer structure 16 being located above the magnetic reference layer 10, or the orientation can be rotated 180° such that the magnetic reference layer 10 is located above the magnetic free layer structure 16. In such an embodiment, the second magnetic free layer 22 would represent a bottommost element of the MTJ pillar of FIG. 2.

The MTJ pillar shown in FIG. 2 can be formed by first providing a MTJ stack that includes blanket layers of the various MTJ pillar materials. The blanket layers of the MTJ pillar materials can be formed by utilizing one or more deposition processes such as, for example, plating, sputtering, plasma enhanced atomic layer deposition (PEALD), plasma enhanced chemical vapor deposition (PECVD) or physical vapor deposition (PVD). After forming the MTJ stack, the MTJ stack is patterned into the MTJ pillar. In some embodiments, the MTJ stack is patterned by etching utilizing a top electrode as an etch mask. In other embodiments, the MTJ stack can be patterned by photolithography and etching.

The magnetic reference layer 10 and the tunnel barrier layer 12 that are used in this embodiment of the present application are the same as those described above for the embodiment depicted in FIG. 1. Thus, the description of the magnetic reference layer 10 and the tunnel barrier layer 12 that are used in this embodiment of the present application is the same as those described above for the embodiment depicted in FIG. 1.

As stated above, the multilayered magnetic free layer structure 16 includes a first magnetic free layer 18 and a second magnetic free layer 22 separated by a non-magnetic layer 20. In this embodiment, the first magnetic layer 18 is compositionally different from the second magnetic free layer 22.

The first magnetic free layer 18 may include a magnetic material or a stacked of magnetic materials with a magnetization that can also be changed in orientation relative to the magnetization orientation of the magnetic reference layer 10. Exemplary materials for the first magnetic free layer 18 include alloys and/or multilayers of cobalt (Co), iron (Fe), alloys of cobalt-iron, nickel (Ni), alloys of nickel-iron, and alloys of cobalt-iron-boron.

The first magnetic free layer 18 has a first perpendicular magnetic anisotropy field which can be from 3 kOe to 10 kOe. The first magnetic free layer 18 has a first thickness which is typically from 1.0 nm to 2.5 nm; although other thicknesses are possible for the first magnetic free layer 18.

The non-magnetic layer 20 of the multilayered magnetic free layer structure 16 is composed of a non-magnetic material that contains at least one element with an atomic number less than 74 such as, for example, beryllium (Be), magnesium (Mg), aluminum (Al), calcium (Ca), boron (B), carbon (C), silicon (Si), vanadium (V), chromium (Cr), titanium (Ti), manganese (Mn) or any combination including alloys thereof. The thickness of the non-magnetic layer 20 is thin enough to allow the first and second magnetic free layers (18, 22) to couple together magnetically so that in equilibrium layers 18 and 22 are always parallel. In one example, the non-magnetic layer 20 has a thickness from 0.3 nm to 3.0 nm.

The second magnetic free layer 22 is composed of a material whose magnetization increases with increasing temperature. Notably, the second magnetic free layer 22 is composed of a ferrimagnetic material, as defined above. In one embodiment, the ferrimagnetic material is a rare earth metal containing transition metal composition, RE-TM, wherein RE is a rare earth metal, as defined above, and TM is a transition metal selected from the group consisting of cobalt (Co), iron (Fe), nickel (Ni), and alloys thereof. That is, RE is one of, scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu).

In one embodiment, the transition metal, TM, of the rare earth metal containing transition metal composition, RE-TM, is an alloy of Co and Fe, and the rare earth metal is one of terbium (Tb) and gadolinium (Gd). In one example, the rare earth metal containing transition metal composition is Tb₁₋ₓ(Fe_{1-y}Co_{y})ₓ, wherein x is from 0.74 to 0.78 and y is from 0.16 to 0.18. In another example, the rare earth metal containing transition metal composition is Tb₁₋ₓ(Fe_{1-y}Co_{y})ₓ, wherein x is 0.76 and y is 0.17.

The second magnetic free layer 22 has a second perpendicular magnetic anisotropy field which can be from 1 kOe to 4 kOe. The second magnetic free layer 22 has a second thickness which is typically, but not necessarily always, greater than the first thickness of the first magnetic free layer 18. In one embodiment, the second thickness of the second magnetic free layer 40 is from 1.5 nm to 4 nm.

In some embodiments (not shown), a MTJ cap layer can be formed as a topmost component of the MTJ pillar of FIG. 2. When present, the MTJ cap layer may be composed of Nb, NbN, W, WN, Ta, TaN, Ti, TiN, Ru, Mo, Cr, V, Pd, Pt, Rh, Sc, Al or other high melting point metals or conductive metal nitrides. The MTJ cap layer may be formed utilizing a deposition process including, for example, CVD, PECVD, ALD, PVD, sputtering, chemical solution deposition or plating. The MTJ cap layer may have a thickness from 2 nm to 25 nm; other thicknesses are possible and can be used in the present application as the thickness of the MTJ cap layer.

The MTJ pillars of FIGS. 1 and 2 can be used in a magnetoresistive random access memory (MRAM) including STT MRAM and can provide such memory with enhanced data retention. In some embodiments, 10 fold increase in data retention can be obtained using one of the MTJ pillars of the present application as compared to an equivalent MTJ pillar which lacks a magnetic free layer that is composed of a ferrimagnetic material, i.e., a material whose magnetization increases with increasing temperature.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A method comprising:
reading data stored in a magnetoresistive random access memory (MRAM) comprising a magnetic tunnel junction (MTJ) pillar having a temperature-independent delta and comprising a tunnel barrier layer located between a magnetic reference layer and a magnetic free layer, wherein the magnetic free layer is composed of a material whose magnetization increases with increasing temperature and the magnetic free layer provides at least a 10 fold increase in data retention as compared to an equivalent MTJ pillar that lacks the magnetic free layer whose magnetization increases with increasing temperature.

2. The method of claim 1, wherein the magnetic free layer is composed of a ferrimagnetic material having a population of atoms with opposing magnetic moments, wherein the opposing magnetic moments are unequal and a spontaneous magnetization remains.

3. The method of claim 2, wherein the ferrimagnetic material is a rare earth metal containing transition metal composition, RE-TM, wherein RE is a rare earth metal, and TM is a transition metal selected from the group consisting of cobalt (Co), iron (Fe), nickel (Ni), and alloys thereof.

4. The method of claim 3, wherein the transition metal, TM, is an alloy of Co and Fe.

5. The method of claim 4, wherein the rare earth metal is one of terbium (Tb) and gadolinium (Gd).

6. The method of claim 3, wherein the rare earth metal containing transition metal composition is Tb₁₋ₓ(Fe_{1-y}CO_{y})ₓ, wherein x is from 0.74 to 0.78 and y is from 0.16 to 0.18.

7. The method of claim 6, wherein x is 0.76 and y is 0.17.

8. The method of claim 1, wherein the magnetic free layer is positioned above the magnetic reference layer.

9. The method of claim 1, wherein the magnetic free layer is positioned beneath the magnetic reference layer.

10. The method of claim 1, wherein the data retention is over a temperature range from −40° C. to 125° C.

11. A method comprising:
reading data stored in a magnetoresistive random access memory (MRAM) comprising a magnetic tunnel junction (MTJ) pillar having a temperature-independent delta and comprising a tunnel barrier layer located between a magnetic reference layer and a multilayered magnetic free layer structure that includes a first magnetic free layer and a second magnetic free layer separated by a non-magnetic layer, wherein the second magnetic free layer is composed of a material whose magnetization increases with increasing temperature and the second magnetic free layer provides at least a 10 fold increase in data retention as compared to an equivalent MTJ pillar that lacks the second magnetic free layer whose magnetization increases with increasing temperature.

12. The method of claim 11, wherein the second magnetic free layer is composed of a ferrimagnetic material.

13. The method of claim 12, wherein the ferrimagnetic material is a rare earth metal containing transition metal composition, RE-TM, wherein RE is a rare earth metal, and TM is a transition metal selected from the group consisting of cobalt (Co), iron (Fe), nickel (Ni), and alloys thereof.

14. The method of claim 13, wherein the transition metal, TM, is an alloy of Co and Fe.

15. The method of claim 14, wherein the rare earth metal is one of terbium (Tb) and gadolinium (Gd).

16. The method of claim 13, wherein the rare earth metal containing transition metal composition is Tb₁₋ₓ(Fe_{1-y}Co_{y})ₓ, wherein x is from 0.74 to 0.78 and y is from 0.16 to 0.18.

17. The method of claim 16, wherein x is 0.76 and y is 0.17.

18. The method of claim 11, wherein the multilayered magnetic free layer structure is positioned above the magnetic reference layer.

19. The method of claim 11, wherein the multilayered magnetic free layer structure is positioned beneath the magnetic reference layer.

20. The method of claim 11, wherein the data retention is over a temperature range from −40° C. to 125° C.
